(19) United States
(12) Patent Application Publication
(10) Pub. No.: US 2026/0109376 A1
(43) Pub. Date: Apr. 23, 2026

(54) OVERHEAD HOIST TRANSPORT DEVICE AND DETECTION METHOD THEREOF

(71) Applicant: NANYA TECHNOLOGY CORPORATION, New Taipei City (TW)

(72) Inventors: Chun Han CHEN, New Taipei City (TW); Zheng-Xun YANG, New Taipei City (TW)

(21) Appl. No.: 18/922,342

(22) Filed: Oct. 21, 2024

(51) Int. Cl. B61K 9/08

(52) U.S. Cl. CPC B61K 9/08

(57) ABSTRACT

A detection method of an overhead hoist transport device includes obtaining a position information of a car at a rail and a vibration information corresponding to the position information. A vibration peak data is generated based on the position information and the vibration information. An analyzing operation is performed on the vibration peak data to generate an analyzed result. Whether the analyzed result indicates a critical gap position at the rail is determined.

### FIELD OF INVENTION

The present invention relates to an overhead hoist transport device and a detection method of the overhead hoist transport device.

### DESCRIPTION OF RELATED ART

Generally, an overhead hoist transport device may be used in a semiconductor automated logistics system for transporting materials in a production site. More specifically, the overhead hoist transport includes cars to deliver different materials in the production site along a rail. The rail includes multiple segments that are assembled together to complete a complex layout. However, gap(s) between various segments of the rail would increase (e.g., equal to or greater than a critical distance) under a long term usage, resulting in internal loads of the cars. As a result, a shaking problem of the car would occur when the cars pass the gaps and the shaking problem may also cause tear on components of the cars.

In this regard, how to provide an overhead hoist transport device and a detection method thereof that can overcome the aforementioned problem is one of the targets in the research and development in the related fields.

### SUMMARY

One aspect of the present disclosure is a detection method of an overhead hoist transport device.

According to some embodiments of the present disclosure, a detection method of an overhead hoist transport device includes obtaining a position information of a car at a rail and a vibration information corresponding to the position information. A vibration peak data is generated based on the position information and the vibration information. An analyzing operation is performed on the vibration peak data to generate an analyzed result. Whether the analyzed result indicates a critical gap position at the rail is determined.

In some embodiment, analyzing the vibration peak data to generate the analyzed result includes converting the vibration peak data into multiple vibration values, calculating the vibration values to generate multiple weighted vibration values, and comparing value differences between the vibration values and the weighted vibration values.

In some embodiment, when one of the value differences is equal to or greater than a predetermined value, the one of the value differences indicates the critical gap position at the rail.

In some embodiment, performing the analyzing operation includes using a graph structure that is integrated by an adjacency relationship of multiple segments of the rail.

In some embodiment, the detection method further includes performing an inspection operation on the critical gap position at the rail.

In some embodiment, the position information of the car at the rail is obtained by a position sensor disposed on the car, and the vibration information is obtained by a vibration sensor disposed on the car.

In some embodiment, the rail has a plurality of barcodes arranged at intervals, and the position sensor identifies the barcodes of the rail to obtain the position information.

In some embodiment, the vibration information is obtained when the car is stopped at one of the barcodes of the rail.

In some embodiment, the vibration information includes a vibration acceleration data of wheels of the car within a period of time.

In some embodiment, the vibration peak data includes a maximum vibration acceleration data of wheels of the car within a period of time.

In some embodiment, the analyzing operation is performed by a logic computing unit.

In some embodiment, the detection method further includes transmitting the position information and the vibration information to the logic computing unit.

Another aspect of the present disclosure is an overhead hoist transport device.

According to some embodiments of the present disclosure, an overhead hoist transport device includes a car, a position sensor, a vibration sensor, and a logic computing unit. The position sensor is disposed on the car and configured to obtain a position information of the car at a rail. The vibration sensor is disposed on the car and configured to obtain a vibration information corresponding to the position information. The logic computing unit is configured to generate a vibration peak data based on the position information and the vibration information, perform an analyzing operation on the vibration peak data to generate an analyzed result, and determine whether the analyzed result indicates a critical gap position at the rail.

In some embodiment, the analyzing operation includes converting the vibration peak data into multiple vibration values, calculating the vibration values to generate multiple weighted vibration values, and comparing value differences between the vibration values and the weighted vibration values.

In some embodiment, when one of the value differences is equal to or greater than a predetermined value, the one of the value differences indicates the critical gap position at the rail.

In some embodiment, the predetermined value is a standard deviation value of the value differences between the vibration values and the weighted vibration values.

In some embodiment, the overhead hoist transport device further includes a transmitting unit electrically connected to the position sensor and the vibration sensor, and the transmitting unit is configured to transmit the position information and the vibration information to the logic computing unit.

In some embodiment, the car has a top portion and a side portion connected to the top portion, and wherein the position sensor and the vibration sensor are disposed on the top portion of the car.

In some embodiment, the overhead hoist transport device further includes a control unit electrically connected to the logic computing unit, and the control unit is configured to perform an inspection operation when the analyzed result indicates the critical gap position at the rail.

In some embodiment, performing the analyzing operation includes using a graph structure that is integrated by an adjacency relationship of multiple segments of the rail.

In the aforementioned embodiments, since the analyzing operation is performed on the vibration peak data to generate the analyzed result, the critical gap position at the rail can be determined or detected. As such, better production efficiency can be achieved. Further, a shaking problem of the car can be avoided and thus tear on components (e.g., wheels or terminal elements) of the car and tear on components (e.g., power lines or signal lines) of the rail can be avoided. Costs and time of manual detection can be also reduced.

### BRIEF DESCRIPTION OF THE DRAWINGS

The invention can be more fully understood by reading the following detailed description of the embodiment, with reference made to the accompanying drawings as follows:

FIG. 1 is a side view of an overhead hoist transport device in accordance with some embodiments of the present disclosure.

FIG. 2 is a bottom view of the overhead hoist transport device in FIG. 1.

FIG. 3 is a block diagram of the overhead hoist transport device in FIG. 1.

FIG. 4 is a flow chart of a detection method of the overhead hoist transport device in accordance with some embodiments of the present disclosure.

FIG. 5 is a flow chart of a detection method of the overhead hoist transport device in accordance with some embodiments of the present disclosure.

FIG. 6 is a schematic diagram of a rail of the overhead hoist transport device in accordance with some embodiments of the present disclosure.

FIG. 7 is a comparison graph showing value differences between vibration values and weighted vibration values in accordance with some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

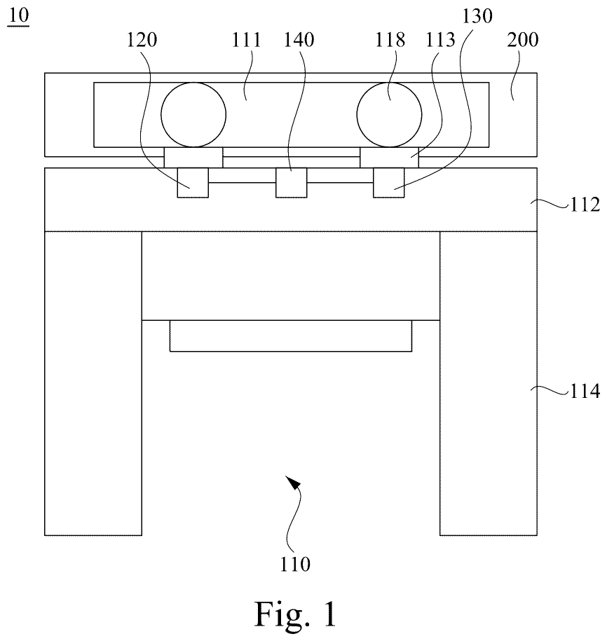

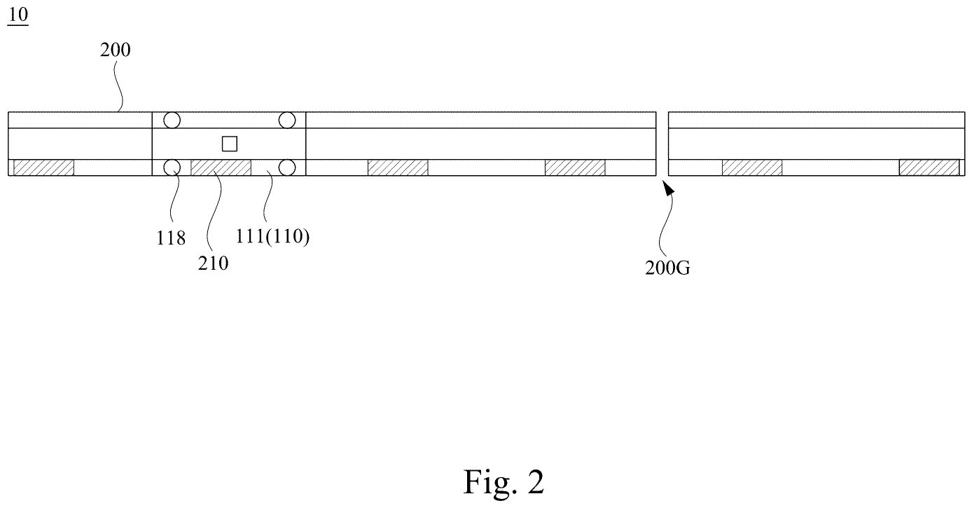

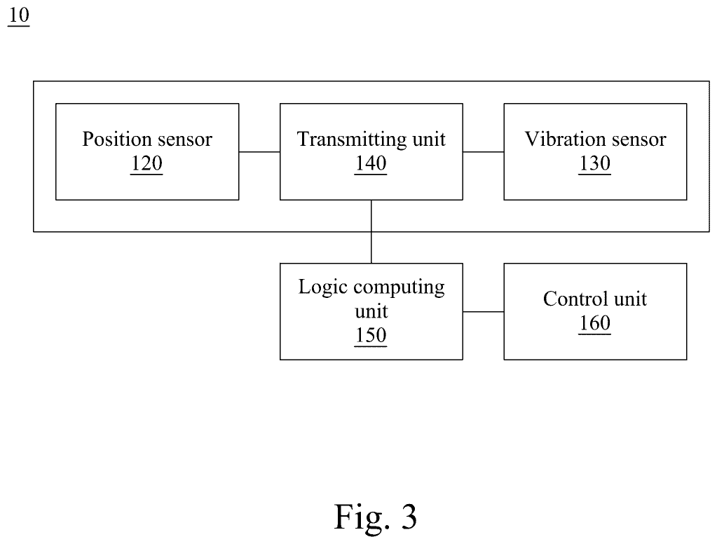

FIG. 1 is a side view of an overhead hoist transport (OHT) device 10 in accordance with some embodiments of the present disclosure, FIG. 2 is a bottom view of the overhead hoist transport device 10 in FIG. 1, and FIG. 3 is a block diagram of the overhead hoist transport device 10 in FIG. 1. Referring to FIGS. 1-3, the overhead hoist transport device 10 includes at least one car 110, a position sensor 120, a vibration sensor 130, and a logic computing unit 150. The position sensor 120 is disposed on the car 110 and configured to obtain a position information of the car 110 at a rail 200. The vibration sensor 130 is disposed on the car 110 and configured to obtain a vibration information corresponding to the position information. The logic computing unit 150 is configured to generate a vibration peak data based on the position information and the vibration information, perform an analyzing operation on the vibration peak data to generate an analyzed result, and determine whether the analyzed result indicates a critical gap position at the rail 200. With the configuration of the overhead hoist transport device 10, better production efficiency can be achieved. Further, a shaking problem of the car 110 can be avoided and thus tear on components (e.g., wheels or terminal elements) of the car 110 and tear on components (e.g., power lines or signal lines) of the rail 200 can be avoided. Costs and time of manual detection can be also reduced.

The overhead hoist transport device 10 includes a transmitting unit 140 electrically connected to the position sensor 120, the vibration sensor 130, and the logic computing unit 150. The transmitting unit 140 is configured to transmit the position information and the vibration information to the logic computing unit 150. In some embodiments, the transmitting unit 140 is electrically connected to the position sensor 120, the vibration sensor 130, and the logic computing unit 150 via a wireless connection.

The overhead hoist transport device 10 includes a control unit 160 electrically connected to the logic computing unit 150. The control unit 160 is configured to perform an inspection operation on the critical gap position at the rail 200 when the analyzed result indicates the critical gap position at the rail 200. In other words, when the analyzed result does not indicate the critical gap position at the rail 200 (i.e., analyzed result indicating that the critical gap position does not exist), the inspection operation is not performed.

In some embodiments, the analyzing operation includes a graph structure (or referred to as a graph structure model or a graph structure method), in which the graph structure is integrated by an adjacency relationship of multiple segments of the rail 200 (e.g., physical distances of the segments of the rail 200). In some embodiments, the analyzing operation includes converting the vibration peak data into multiple vibration values, calculating the vibration values to generate multiple weighted vibration values, and comparing value differences between the vibration values and the weighted vibration values. In greater details, the logic computing unit 150 is configured to convert the vibration peak data into the vibration values at various positions (i.e., different barcodes 210) of the rail 200, configured to calculate the vibration values at various positions (i.e., different barcodes 210) of the rail 200 to generate the weighted vibration values, and further configured to compare value differences between the vibration values and the weighted vibration values. In some embodiments, comparing the value differences between the vibration values and the weighted vibration values includes calculating the vibration values and the weighted vibration values to obtain the value differences and further includes comparing each of the value differences with a predetermined value. When one of the value differences is equal to or greater than the predetermined value, the one of the value differences indicates the critical gap position (i.e., the gap 200G is equal to or greater than a critical distance) at the rail 200; and when the value differences are smaller than the predetermined value, the value differences indicate the critical gap position does not exist at the rail 200 (i.e., the gap 200G is smaller than a critical distance). In some embodiments, the predetermined value may be calculated by the logic computing unit 150 from all of the value differences between the vibration values and the weighted vibration values. In some embodiments, the overhead hoist transport device 10 further includes a database unit, and the predetermined value is stored in the database unit.

In some embodiments, the predetermined value is used to determine whether the value differences are deviate from a normal distribution, thereby determining whether the gap 200G equal to or greater than a critical distance is at the position corresponding to the value difference. In some embodiments, the predetermined value is a standard deviation value (e.g., one standard deviation value or two standard deviation value) of the value differences between the vibration values and the weighted vibration values. Alternative, the predetermined value is a mean value, a mean change value, or a standard deviation change value.

In some embodiments, the car 110 has a top portion 112 and a side portion 114 connected to the top portion 112. The top portion 112 of the car 110 is closer to the rail 200 than the side portion 114 of the car 110. In greater details, the top portion 112 of the car 110 has a connecting segment 111. The connecting segment 111 is positioned on the rail 200 for allowing the car 110 to move along the rail 200. The side portion 114 of the car 110 is used to reach downwards to pick up an object (e.g., wafer cassette) when the car 110 is in a stationary state. For example, the control unit 160 is configured to provide a first control signal to operate the connecting segment 111 to move along the rail 200, and the control unit 160 is configured to provide a second control signal to operate the side portion 114 to pick up an object. In some embodiments, since the vibration sensor 130 is disposed on the top portion 112 of the car 110, the accuracy of the vibration information can be improved. In some embodiments, the vibration sensor 130 is a gyroscope. In some embodiments, the position sensor 120, the vibration sensor 130, and the transmitting unit 140 are disposed on the top portion 112 of the car 110.

In some embodiments, the rail 200 has a plurality of barcodes 210 arranged at intervals. The barcodes 210 may be one-dimensional codes or two-dimensional codes. The position sensor 120 is configured to identify the barcodes 210 of the rail 200 to obtain the position information.

In some embodiments, multiple cars 110 move along the rail 200 at the same time. The number of the cars 110 may be two, three, or more, but the present disclosure is not limited thereto. In order to exclude the vibration caused by the car itself (e.g., the car 110 in FIG. 2) and/or the cross-influence of the car (e.g., the car 110 in FIG. 2) and other cars (not shown), the vibration information is obtained when the car 110 is stopped (i.e., in a stationary state) at one of the barcodes 210 of the rail 200. In other word, the vibration information is related to the vibration caused by other moving cars (particularly the moving car closest to the stopped car) at the rail 200.

In some embodiments, the car 110 includes wheels 118 disposed on the connecting segment 111 of the top portion 112. The wheels 118 include driving wheels and driven wheels, in which the driven wheels are used to support a weight of an entirety of the car 110. In some embodiments, vibration information includes a vibration acceleration data of wheels 118 (e.g., driven wheels) of the car 110 within a period of time. The vibration caused by the other cars passing through a gap 200G mainly comes from the driven wheels, and a waveform of the vibration acceleration of the driven wheels within a period of time may have a two peak shape, in which the acceleration difference between the two peaks (i.e., two maximum vibration acceleration) is less than 5%. In other words, the two peaks (i.e., two maximum vibration acceleration) are approximately the same. In some embodiments, in order to exclude the influence of vibrations (i.e., superposition of waves) caused by other cars (not shown) at different positions at the same time, the logic computing unit 150 is configured to capture (or retrieve) a maximum vibration acceleration data of the vibration acceleration data of the vibration information and thus the vibration peak data is generated based on the position information and the vibration information. As a result, the accuracy of determining the critical gap position can be improved.

In some embodiments, when a greater vibration peak data is generated at the same position of the rail 200, the logic computing unit 150 is further configured to replace the original vibration peak data with the greater vibration peak data.

In some embodiments, the car 110 further includes two orientation portions 113 configured to allow the car 110 to turn (or adjust its orientation). Specifically, the driven wheels 118 are divided into a two groups (e.g., front driven wheel and rear driven wheel). The position sensor 120 and the vibration sensor 130 are respectively disposed on the two orientation portions 113 of the car 110. The orientation portions 113 are connected to a main body (e.g., the connecting segment 111, the top portion 112, and the side portion 114) of the car 110 such that the orientation portions 113 can be turned, thereby turning the main body of the car 110. In some embodiments, the rail 200 includes multiple segments that are assembled together to complete a complex layout. The overhead hoist transport device 10 of the present disclosure can be applied to any kind of overhead hoist transport device with minor correction (e.g., a model of vibration, an assembling method the rail, and a supporting method of the rail).

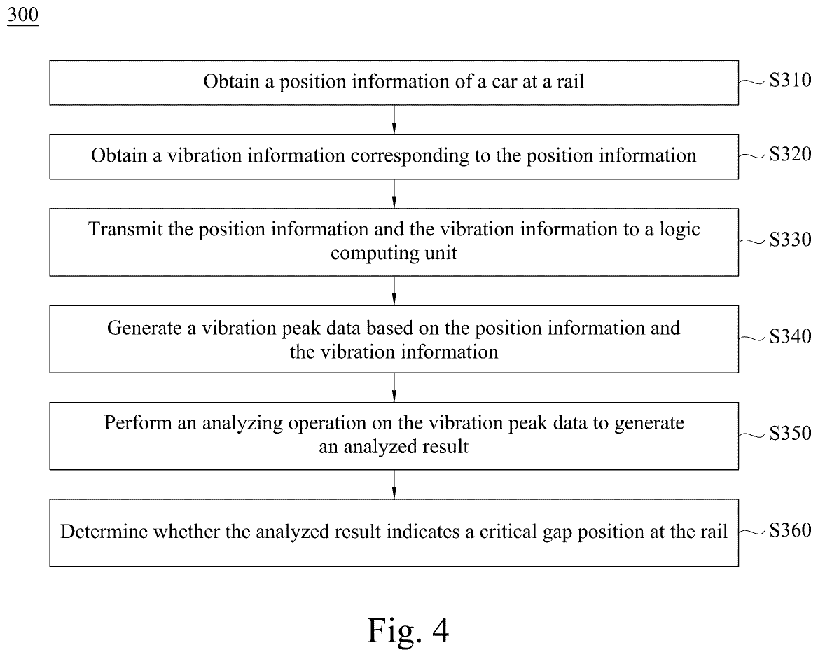

Reference is now made to FIG. 4. FIG. 4 is a flow chart of a detection method 300 of the overhead hoist transport device in accordance with some embodiments of the present disclosure. It is understood that additional steps can be provided before, during, and after the detection method 300 shown by FIG. 4, and some of the steps described below can be replaced or eliminated, for additional embodiments of the detection method 300. The detection method 300 may include steps S310, S320, S330, S340, S350, and S360 that are described in more detail below with reference to FIGS. 1-4, and the detection method 300 may be performed by the overhead hoist transport device 10 as shown in FIGS. 1-3.

The detection method 300 begins at step S310, where a position information of a car at a rail is obtained. Referring to FIGS. 1-4, in some embodiments of the step S310, the position information of the car 110 at the rail 200 is obtained by the position sensor 120 that is disposed on the car 110. In some embodiments, the position sensor 120 reads (or identifies) the barcodes 210 of the rail 200 to obtain the position information.

At step S320, a vibration information corresponding to the position information is obtained. Referring to FIGS. 1-4, in some embodiments of the step S320, the vibration information corresponding to the position information is obtained by the vibration sensor 130 that is disposed on the car 110. The vibration information includes a vibration acceleration data of the wheels 118 (e.g., driven wheels) of the car 110 within a period of time. In some embodiments, the vibration information is obtained when the car 110 is stopped (i.e., in a stationary state) at one of the barcodes 210 of the rail 220. In some embodiments, the vibration information corresponding to the position information is obtained after obtaining the position information of the car 110 at the rail 200. In some embodiments, the vibration information corresponding to the position information is obtained while obtaining the position information of the car 110 at the rail 200.

At step S330, the position information and the vibration information are transmitted to a logic computing unit. Referring to FIGS. 1-4, in some embodiments of the step S330, the transmitting unit 140 is configured to transmit the position information and the vibration information to the logic computing unit 150. The transmitting unit 140 is electrically connected to the position sensor 120, the vibration sensor 130, and the logic computing unit 150. The position sensor 120, the transmitting unit 140, and the vibration sensor 130 are disposed on the top portion 112 of the car 110 such that the accuracy of the vibration information can be improved.

At step S340, a vibration peak data is generated based on the position information and the vibration information. Referring to FIGS. 1-4, in some embodiments of the step S340, the logic computing unit 150 is configured to generate the vibration peak data based on the position information and the vibration information. In some embodiments, the vibration peak data includes a maximum vibration acceleration data of the wheels 118 (e.g., the driven wheels) of the car 110 within a period of time.

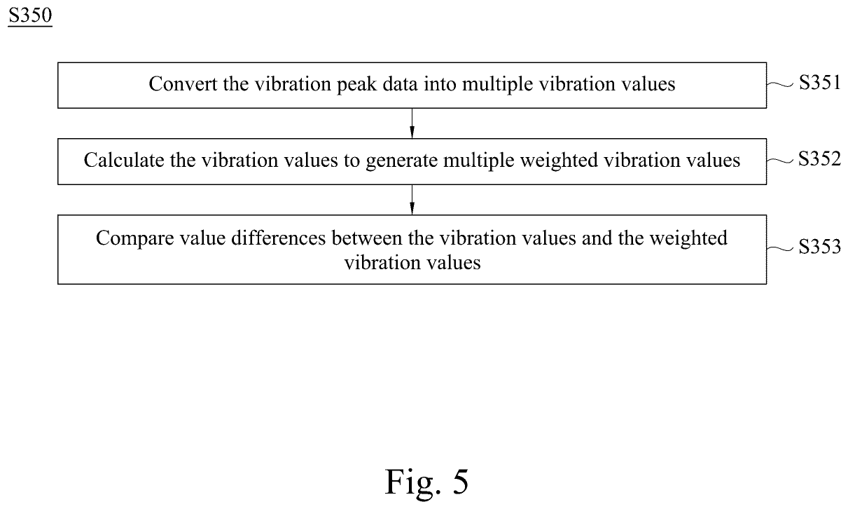

The detection method 300 proceeds to step S350, where an analyzing operation is performed on the vibration peak data to generate an analyzed result. Referring to FIGS. 1-4, in some embodiments of the step S350, the logic computing unit 150 is configured to perform the analyzing operation on the vibration peak data to generate the analyzed result. In some embodiments, performing the analyzing operation includes using a graph structure (or referred to as a graph structure model), in which the graph structure is integrated by an adjacency relationship of multiple segments of the rail 200 (e.g., physical distances of the segments of the rail 200). In some embodiments, the step S350 includes steps S351-S353 and can be performed by using the overhead hoist transport device 10 illustrated in FIGS. 1-3. FIG. 5 is a flow chart of the step S350 of the detection method 300 of FIG. 4 in accordance with some embodiments of the present disclosure. The flow chart shown in FIG. 5 is merely an example, and is not intended to limit the present disclosure beyond what is explicitly recited in the claims. It is understood that additional steps can be provided before, during, and after the steps shown by FIG. 5, and some of the steps described below can be replaced or eliminated, for additional embodiments of the steps of FIG. 5.

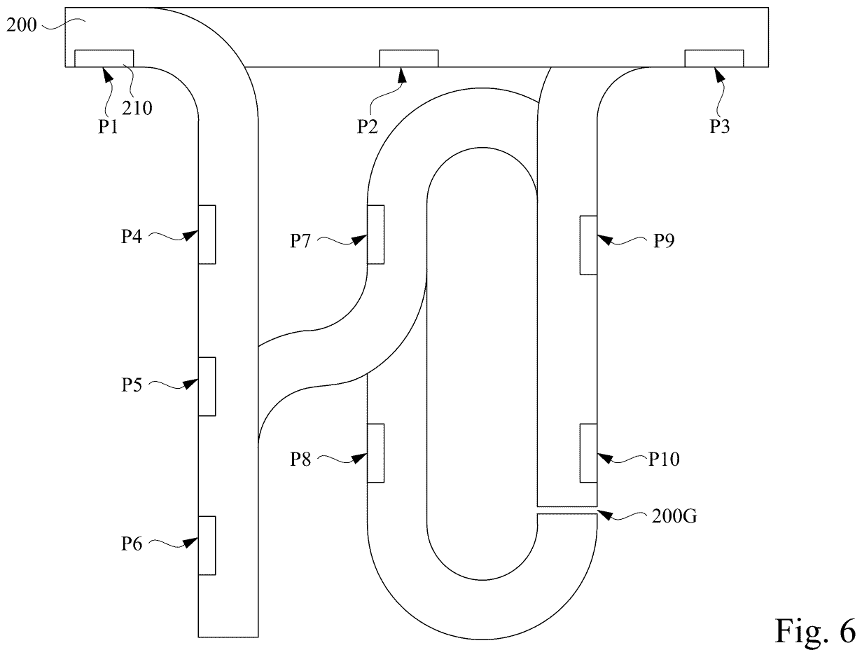

At step S351, the vibration peak data is converted into multiple vibration values. Referring to FIGS. 1-5, in some embodiments of the step S351, the logic computing unit 150 is configured to convert the vibration peak data into the vibration values at various positions (i.e., different barcodes 210) of the rail 200. In some embodiments, the logic computing unit 150 is configured to convert the maximum vibration acceleration data of the vibration peak data into the vibration values. FIG. 6 is a schematic diagram of the rail 200 of the overhead hoist transport device in accordance with some embodiments of the present disclosure. As shown in FIGS. 3 and 6, the vibration peak data includes the maximum vibration acceleration data at positions P1-P10 (i.e., positions where different barcodes 210 are located) of the rail 200, and the logic computing unit 150 is configured to convert the maximum vibration acceleration data into various vibration values at the positions P1-P10 of the rail 200. In some embodiments, the maximum vibration acceleration data of the vibration peak data are converted by the logic computing unit 150 using a function, a machine learning algorithm, or a training data set to generate the vibration values. In some embodiments, converting the vibration peak data into the vibration values includes using the graph structure. In greater details, the logic computing unit 150 uses the graph structure to generate an ordered graph representing a distance relationship of the segments (positions, such as positons P1-P10) of the rail 200. Since vibration has no directionality and adjacent segments of the rail 200 can transmit the vibration, the ordered graph is modified/corrected to an unordered graph representing an adjacency relationship of the segments (positions, such as positons P1-P10) of the rail 200. In some embodiments, the vibration peak data is converted into multiple vibration values by using a regression method. The vibration acceleration data caused by the car 110 at one position on the rail 200 is regressed (or converted) to the vibration values at a standard speed (e.g., assuming that each car 110 passing the position on the rail 200 with the same speed), thereby obtaining a degree of discontinuity (e.g., gap 200G) on the rail 200. For example, the cars 110 at the rail 200 may have different speeds. By regressing the different speeds of the cars 110 to the same standard speed, the vibration values based on the vibration peak data can be calculated more accurate.

At step S352, the vibration values are calculated to generate multiple weighted vibration values. Referring to FIGS. 1-5, in some embodiments of the step S352, the logic computing unit 150 is configured to calculate the vibration values to generate the weighted vibration values. In some embodiments, as shown in FIGS. 3 and 6, the vibration values at the positions P1-P10 are calculated to generate the weighted vibration values. In some embodiments, the vibration values are calculated by the logic computing unit 150 using a numerical analysis method, a function, a machine learning algorithm, or a training data set to generate the weighted vibration values. In some embodiments, calculating the vibration values to generate the weighted vibration values is performed by using the graph structure. In some embodiments, generating the weighted vibration values includes analyzing a connecting degree (e.g., adjacency relationship) and a length of each segment of the rail 200. In some embodiments, the vibration values are calculated by using a polarization operation (e.g., Laplacian operator in image processing). The amount of the weight is related to the distance of two of the points (e.g., any two positions of the positions P1-P10) on the rail 200. For example, the adjacent points on the rail 200 (e.g., one position P9 and another position P10 close to the position P9) will have a higher weight than non-adjacent points on the rail 200. In some embodiments, generating the weighted vibration values includes performing a breadth-first search (BFS) on each point (e.g., positions P1-P10) of an unordered graph representing an adjacency relationship of the segments on the rail 200. A degree of discontinuity (e.g., gap 200G) on the rail 200 can be thus obtained.

At step S353, value differences between the vibration values and the weighted vibration values are compared. Referring to FIGS. 1-5, in some embodiments of the step S353, the logic computing unit 150 is configured to compare the value differences between the vibration values and the weighted vibration values. In some embodiments, comparing the value differences between the vibration values and the weighted vibration values includes calculate the vibration values and the weighted vibration values to obtain the value differences therebetween and further includes comparing each of the value differences with a predetermined value.

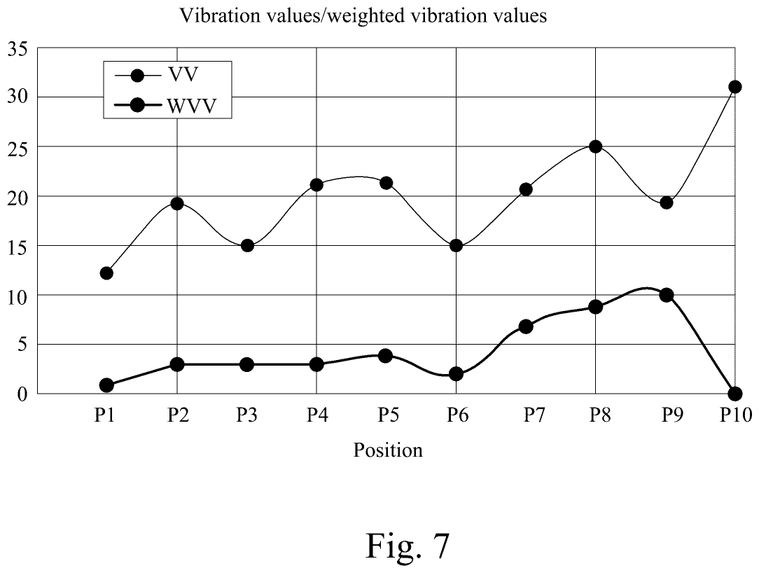

In some embodiments, the logic computing unit 150 is configured to compare the value differences between the vibration values and the weighted vibration values to generate a comparison graph (or a comparison result), and the logic computing unit 150 is further configured to generate the analyzed result based on the comparison graph (or the comparison result). FIG. 7 is a comparison graph showing value differences between the vibration values and the weighted vibration values in accordance with some embodiments of the present disclosure. As shown in FIGS. 3 and 5-7, curve VV shows the vibration values at positions P1-P10 (i.e., positions where different barcodes 210 are located) on the rail 200, and curve WVV shows the weighted vibration values at positions P1-P10 on the rail 200. The logic computing unit 150 analyzes the comparison graph (e.g., comparison graph of FIG. 7) to determine whether the value differences are deviate from a normal distribution and then generates the analyzed result based on the comparison graph. In other words, the logic computing unit 150 is configured to compare each of the value differences and a predetermined value. For example, at the position P10, the value difference between the vibration value and the weighted vibration value is equal to or greater than a predetermined value (e.g., one standard deviation value, two standard deviation value, or other suitable standard deviation value); while at the positions P1-P9, the value differences between the vibration values and the weighted vibration values are smaller than the predetermined value. In some embodiments, the logic computing unit 150 is further configured to classify the value differences according to different types of the segments of the rail 200. For example, the rail 200 has straight segments and curved segments. The value difference corresponding to one of the straight segments of the rail 200 is compared with the predetermined value (e.g., standard deviation value) corresponding to the straight segment of the rail 200, and the value difference corresponding to one of the curved segments of the rail 200 is compared with the predetermined value (e.g., standard deviation value) corresponding to the curved segment of the rail 200.

The detection method 300 proceeds to step S360, where whether the analyzed result indicates a critical gap position at the rail is determined. Referring to FIGS. 1-7, in some embodiments of the step S360, the logic computing unit 150 is configured to determine whether the analyzed result indicates a critical gap position (e.g., the gap 200G equal to or greater than a critical distance) at the rail 200. In some embodiments, when one of the value differences corresponding to one position is equal to or greater than the predetermined value, the one of the value differences indicates gap 200G at the one positon is equal to or greater than a critical distance (i.e., the critical gap position); and when the value differences corresponding to other positions are smaller than the predetermined value, the value differences indicate the gaps 200G at the other positions are smaller than the critical distance (i.e., the critical gap position does not exist). In some embodiments, as shown in FIGS. 6-7, the value difference at the position P10 is equal to or greater than the predetermined value and thus the analyzed result corresponding to the value difference indicates the critical gap position (i.e., the gap 200G at position P10 equal to or greater than the critical distance) is at (or close to) the position P10, while the value differences at the positions is smaller than the predetermined value and thus the analyzed result corresponding to the value differences indicate no critical gap position at (or close to) the positions P1-P9 (i.e., the gap 200G at positions P1-P9 smaller than the critical distance).

After the step S360, the detection method 300 further includes transmitting the analyzed result to the control unit 160. After the step S360, the detection method 300 further includes performing a subsequent operation based on the analyzed result. In some embodiments, the control unit 160 is configured to perform the subsequent operation based on the analyzed result. When the analyzed result indicates the critical gap position at the rail 200, the control unit 160 is configured to perform the inspection operation on the critical gap position at the rail 200 based on the analyzed result. In contrast, when the analyzed result indicates no the critical gap position at the rail 200, the control unit 160 is configured not to perform the inspection operation based on the analyzed result and configured to perform the step S310. In some embodiments, the rail 200 includes adjustment strips, and the inspection operation includes transmitting a control signal by the control unit 160 to compress the adjustment strips such that the gap 200G is narrowed (e.g., a distance of the gap 200G is decreased to smaller than a critical distance).

In some embodiments, the detection method 300 further includes generating a process/product report by the logic computing unit 150 based on the analyzed result. The process/product report may be transmitted to the database unit of the overhead hoist transport device 10 for the supervisor operators to review.

It should be noted that the overhead hoist transport device 10 depicted in FIG. 3 may also include a processing device for realizing one or more of the tools, systems, methods, or operations described with respect to FIGS. 1-7.

In summary, the analyzing operation is performed on the vibration peak data to generate the analyzed result, and the critical gap position at the rail can be determined. As such, better production efficiency can be achieved. Further, a shaking problem of the car can be avoided and thus tear on components (e.g., wheels or terminal elements) of the car and tear on components (e.g., power lines or signal lines) of the rail can be avoided. Costs and time of manual detection can be also reduced.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A detection method of an overhead hoist transport device, comprising:
obtaining a position information of a car at a rail and a vibration information corresponding to the position information;
generating a vibration peak data based on the position information and the vibration information;
performing an analyzing operation on the vibration peak data to generate an analyzed result; and
determining whether the analyzed result indicates a critical gap position at the rail.

2. The detection method of claim 1, wherein analyzing the vibration peak data to generate the analyzed result comprises:
converting the vibration peak data into multiple vibration values;
calculating the vibration values to generate multiple weighted vibration values; and
comparing value differences between the vibration values and the weighted vibration values.

3. The detection method of claim 2, wherein when one of the value differences is equal to or greater than a predetermined value, the one of the value differences indicates the critical gap position at the rail.

4. The detection method of claim 1, wherein performing the analyzing operation comprises using a graph structure that is integrated by an adjacency relationship of multiple segments of the rail.

5. The detection method of claim 1, further comprising:
performing an inspection operation on the critical gap position at the rail.

6. The detection method of claim 1, wherein the position information of the car at the rail is obtained by a position sensor disposed on the car, and wherein the vibration information is obtained by a vibration sensor disposed on the car.

7. The detection method of claim 6, wherein the rail has a plurality of barcodes arranged at intervals, and the position sensor identifies the barcodes of the rail to obtain the position information.

8. The detection method of claim 7, wherein the vibration information is obtained when the car is stopped at one of the barcodes of the rail.

9. The detection method of claim 1, wherein the vibration information comprises a vibration acceleration data of wheels of the car within a period of time.

10. The detection method of claim 1, wherein the vibration peak data comprises a maximum vibration acceleration data of wheels of the car within a period of time.

11. The detection method of claim 1, wherein the analyzing operation is performed by a logic computing unit.

12. The detection method of claim 11, further comprising:
transmitting the position information and the vibration information to the logic computing unit.

13. An overhead hoist transport device, comprising:
a car;
a position sensor disposed on the car and configured to obtain a position information of the car at a rail;
a vibration sensor disposed on the car and configured to obtain a vibration information corresponding to the position information; and
a logic computing unit configured to:
generate a vibration peak data based on the position information and the vibration information;
perform an analyzing operation on the vibration peak data to generate an analyzed result; and
determine whether the analyzed result indicates a critical gap position at the rail.

14. The overhead hoist transport device of claim 13, wherein the analyzing operation comprises:
converting the vibration peak data into multiple vibration values;
calculating the vibration values to generate multiple weighted vibration values; and
comparing value differences between the vibration values and the weighted vibration values.

15. The overhead hoist transport device of claim 14, wherein when one of the value differences is equal to or greater than a predetermined value, the one of the value differences indicates the critical gap position at the rail.

16. The overhead hoist transport device of claim 15, wherein the predetermined value is a standard deviation value of the value differences between the vibration values and the weighted vibration values.

17. The overhead hoist transport device of claim 13, further comprising:
a transmitting unit electrically connected to the position sensor and the vibration sensor, wherein the transmitting unit is configured to transmit the position information and the vibration information to the logic computing unit.

18. The overhead hoist transport device of claim 13, wherein the car has a top portion and a side portion connected to the top portion, and wherein the position sensor and the vibration sensor are disposed on the top portion of the car.

19. The overhead hoist transport device of claim 13, further comprising:
a control unit electrically connected to the logic computing unit, wherein the control unit is configured to perform an inspection operation when the analyzed result indicates the critical gap position at the rail.

20. The overhead hoist transport device of claim 13, wherein performing the analyzing operation comprises using a graph structure that is integrated by an adjacency relationship of multiple segments of the rail.
